(19) United States
(12) Patent Application Publication
(10) Pub. No.: US 2003/0148631 A1
(43) Pub. Date: Aug. 7, 2003

(54) Oxidative annealing method for forming etched spin-on-glass (SOG) planarizing layer with uniform etch profile

(75) Inventors: Hsi-Shan Kuo, Taipei (TW); Wei-Kun Yeh, Hsin-Chu (TW)

Correspondence Address: George O. Saile, 28 Davis Avenue, Poughkeepsie, NY, 12603, US

(73) Assignee: TAIWAN SEMICONDUCTOR MANUFACTURING COMPANY

(21) Appl. No.: 10/361,735

(22) Filed: Feb. 10, 2003

Related U.S. Application Data
(63) Continuation of application No. 09/435,670, filed on Nov. 8, 1999, now abandoned.

(51) Int. Cl. H01L 21/31

(52) U.S. Cl. 438/782

(57) ABSTRACT

Within a method for forming a spin-on-glass (SOG) layer there is first provided a substrate. There is then formed over the substrate a spin-oil-glass (SOG) planarizing layer while employing a silsesquioxane spin-on-glass (SOG) planarizing material. There is then annealed thermally the spin-on-glass (SOG) planarizing layer while employing a first thermal annealing method employing a first gaseous atmosphere comprising a non-oxidizing gas to form a cured spin-on-glass (SOG) planarizing layer. Finally, there is then annealed thermally the cured spin-on-glass (SOG) planarizing layer while employing a second thermal annealing method employing a second gaseous atmosphere comprising an oxidizing gas to form firm the cured spin-on-glass (SOG) planarizing layer an oxidized cured spin-on-glass (SOG) planarizing layer. The oxidized cured spin-on-glass (SOG) planarizing layer when subsequently etched exhibits a more uniform etch profile, and the oxidized cured spin-on-glass (SOG) planarizing layer also exhibits enhanced adhesion to additional layers formed thereupon.

### BACKGROUND OF THE INVENTION

1. Field of the Invention

The present invention relates generally to methods for forming dielectric layers within microelectronic fabrications. More particularly, the present invention relates to methods for forming spin-on-glass (SOG) planarizing dielectric layers within microelectronic fabrications.

2. Description of the Related Art

Microelectronic fabrications are formed from microelectronic substrates over which are formed patterned microelectronic conductor layers which are separated by microelectronic dielectric layers.

As microelectronic device and patterned microelectronic conductor layer dimensions have decreased, it has become increasingly important within the art of microelectronic fabrication to fabricate microelectronic fabrications with dielectric layers which efficiently fill narrow pitch dimension spacings separating microelectronic devices and patterned microelectronic conductor layers within microelectronic fabrications.

Of the materials which are of interest for efficiently filling, narrow pitch dimension spacings separating microelectronic devices and patterned microelectronic conductor layers within microelectronic fabrications, spin-on-glass (SOG) planarizing dielectric materials are of particular interest insofar as they may be readily formed employing spin coating methods as are conventional in the art of microelectronic fabrication. More particularly, silsesquioxane spin-on-glass (SOG) planarizing dielectric materials are even more desirable within the art of microelectronic fabrication insofar as in addition to being readily formed employing spin coating methods as are conventional in the art of microelectronic fabrication, silsesquioxane spin-on-glass (SOG) planarizing dielectric materials also possess generally lower dielectric constants (in a range of from about 3.1 to about 3.6) in comparison with either: (1) silicate spin-on-glass (SOG) planarizing dielectric materials; or (2) other non-planarizing dielectric materials such as silicon oxide dielectric materials, silicon nitride dielectric materials and silicon oxynitride dielectric materials, as are conventionally employed within the art of microelectronic fabrication and typically possess a dielectric constant in a range of from about 3.6 to about 4.0.

As is understood by a person skilled in the art a silsesquioxane spin-on-glass (SOG) dielectric material is characterized by the chemical formula R₁Si(OR₂)₃, where R₁ may include, but is not limited to a hydrogen radical (hydrogen silsesquioxane), a carbon bonded hydrocarbon radical such as methyl radical or ethyl radical (methyl silsesquioxane or ethyl silsesquioxane) or a carbon bonded perfluorocarbon radical such as perfluoromethyl radical or perfluoroethyl radical (perfluoromethyl silsesquioxane or perfluoroethyl silsesquioxane), while R₂ is typically a methyl radical or an ethyl radical.

While silsesquioxane spin-on-glass (SOG) planarizing dielectric materials are thus presently of interest for filling narrow pitch dimension spacings separating microelectronic devices and patterned microelectronic conductor layers within microelectronic fabrications, silsesquioxane spin-on-glass (SOG) planarizing dielectric materials are not without problems when employed for filling narrow pitch dimension spacings separating microelectronic devices and patterned microelectronic conductor layers within microelectronic fabrications. In that regard, it is often difficult to at least either: (1) form through layers formed of silsesquioxane spin-on-glass (SOG) planarizing dielectric materials formed within microelectronic fabrications vias with uniform etch profiles (i.e. uniform sidewall profiles); or (2) form upon layers formed of silsesquioxane spin-on-glass (SOG) planarizing dielectric materials within microelectronic fabrications overlying layers with enhanced adhesion.

It is thus towards the goal of forming within the art of microelectronic fabrication layers formed of silsesquioxane spin-on-glass (SOG) planarizing dielectric materials in accord with the foregoing objects that the present invention is directed.

Various methods have been disclosed in the art of microelectronic fabrication for forming layers of spin-on-glass (SOG) planarizing dielectric materials within microelectronic fabrications and/or for employing layers of spin-on-glass (SOG) planarizing dielectric materials within microelectronic fabrications.

For example, Malazgirt et al., in U.S. Pat. No. 4,986,878, discloses a method for planarizing within a microelectronic fabrication a topographic substrate layer to provide a planarized topographic substrate layer with enhanced dielectric passivation within the microelectronic fabrication. The method employs a spin-on-glass (SOG) planarizing dielectric material which is employed as a sacrificial etchback planarizing layer when reactive ion etch (RIE) etchback planarizing a conformal dielectric layer which comprises the topographic substrate layer within the microelectronic fabrication, where the spin-on-glass (SOG) planarizing dielectric material is completely stripped from the reactive ion etch (RIE) etchback planarized conformal dielectric layer prior to forming upon the reactive ion etch (RIE) etchback planarized conformal dielectric layer an additional planarizing dielectric layer.

In addition, Ouellet, in U.S. Pat. No. 5,320,983, discloses a method for forming within a microelectronic fabrication a spin-on-glass (SOG) planarizing dielectric layer with attenuated cracking within the spin-on-glass (SOG) planarizing dielectric layer. The method employs forming the spin-on-glass (SOG) planarizing dielectric layer as a spin-on-glass (SOG) planarizing multi-layer dielectric layer, where each layer within the spin-on-glass (SOG) planarizing multi-layer dielectric layer is thermally cured at a temperature of at least about 300 degrees centigrade prior to forming thereupon an additional layer within the spin-on-glass (SOG) planarizing multi-layer dielectric layer.

Further, Reinhart, in U.S. Pat. No. 5,290,399, discloses a method for planarizing within a microelectronic fabrication side surfaces of a topographic microelectronic substrate while employing a spin-on-glass (SOG) planarizing dielectric material and while similarly avoiding cracking within the spin-on-glass (SOG) planarizing dielectric material. The method employs forming a blanket spin-on-glass (SOG) planarizing dielectric layer upon the topographic microelectronic substrate, and then partially curing and etching back the blanket spin-on-glass (SOG) planarizing dielectric layer prior to oxygen plasma treating the partially cured and etched back blanket spin-on-glass (SOG) planarizing dielectric layer.

Still further, Takeshiro, in U.S. Pat. No. 5,316,980, discloses a reactive ion etch (RIE) etchback planarizing method for forming with enhanced planarity within a microelectronic fabrication a planarized dielectric layer from a composite dielectric layer comprising a spin-on-glass (SOG) planarizing dielectric layer formed upon a conformal dielectric layer in turn formed upon a topographic substrate layer. The reactive ion etch (RIE) etchback planarization method employs a hexafluoroethane etchant gas at a substrate temperature and a flow rate such that an etch rate ratio of the conformal dielectric layer to the spin-on-glass (SOG) planarizing dielectric layer is from about 1.5 to about 2.0.

Similarly, Weling et al., in U.S. Pat. No. 5,378,318, also disclose a reactive ion etch (RIE) etchback method for forming within a microelectronic fabrication a planarized dielectric layer employing a reactive ion etch (RIE) etchback planarization of a composite dielectric layer comprising a spin-on-glass (SOG) planarizing dielectric layer formed upon a conformal dielectric layer formed upon a topographic substrate layer. The method employs a conformal dielectric layer formed of a silicon rich silicon oxide such that there is attenuated a sensitivity of a reactive ion etch (RIE) etchback rate to certain parameters, such as relative exposed area of the silicon rich silicon oxide layer exposed incident to the reactive ion etch (RIE) etchback method.

Yet still further, Wang et al., in U.S. Pat. No. 5,567,658, disclose a reactive ion etch (RIE) etchback planarizing method for forming within a microelectronic fabrication a reactive ion etch (RIE) etchback planarized spin-on-glass (SOG) planarizing layer to which there may be formed with enhanced adhesion an overlying layer within the microelectronic fabrication. The method employs a fluorocarbon plasma for reactive ion etch (RIE) etchback planarizing the spin-on-glass (SOG) planarizing layer, followed by a nitrous oxide or a nitrogen plasma for treating the reactive ion etch (RIE) etchback planarized spin-on-glass (SOG) planarizing layer to provide the enhanced adhesion to the overlying layer within the microelectronic fabrication.

Finally, Huang, in U.S. Pat. No. 5,679,211, discloses a reactive ion etch (RIE) etchback method for forming within a microelectronic fabrication a reactive ion etch (RIE) etchback planarized spin-on-glass (SOG) layer with greater uniformity. The method employs interposed between sequential incremental reactive ion etch (RIE) etchback planarizing of the spin-on-glass (SOG) planarizing layer sequential removal of a series of reactive ion etch (RIE) etchback polymer residues while employing an oxygen containing plasma.

Desirable in the art of microelectronic fabrication are additional methods and materials which may be employed to form within microelectronic fabrications silsesquioxane spin-on-glass (SOG) planarizing dielectric layers with enhanced properties, such as: (1) uniform etch profile properties; and (2) enhanced adhesion properties within respect to overlying layers formed thereupon.

It is towards the foregoing (goals that the present invention is directed.

### SUMMARY OF THE INVENTION

A first object of the present invention is to provide a method for forming a spin-on-glass (SOG) planarizing dielectric layer within a microelectronic fabrication.

A second object of the present invention is to provide a method in accord with the first object of the present invention, where the spin-on-glass (SOG) planarizing dielectric layer is formed with enhanced properties, such as but not limited to uniform etch profile properties and enhanced adhesion properties with respect to overlying layers formed thereupon.

A third object of the present invention is to provide a method in accord with the first object of the present invention and the second object of the present invention, which method is readily commercially implemented.

In accord with the objects of the present invention, there is provided by the present invention a method for forming a spin-on-glass (SOG) planarizing dielectric layer within a microelectronic fabrication. To practice the method of the present invention, there is first provided a substrate. There is then formed over the substrate a spill-on-glass (SOG) planarizing layer while employing a silsesquioxane spin-on-glass (SOG) planarizing material. There is then annealed thermally, while employing a first thermal annealing method, the spin-on-glass (SOG) planarizing layer within a first gaseous atmosphere comprising a non-oxidizing gas to form from the spin-on-glass (SOG) planarizing layer a cured spin-on-glass (SOG) planarizing layer. Finally, there is then annealed thermally, while employing a second thermal annealing method, the cured spin-on-glass (SOG) planarizing layer within a second gaseous atmosphere comprising an oxidizing gas to form from the cured spin-on-glass (SOG) planarizing layer an oxidized cured spin-on-glass (SOG) planarizing layer.

There is provided by the present invention a method for forming a spin-on-glass (SOG) planarizing dielectric layer within a microelectronic fabrication, where the spin-on-glass (SOG) planarizing dielectric layer is formed with enhanced properties. The method of the present invention realizes the foregoing object by employing when forming a spin-on-glass (SOG) planarizing layer a thermal annealing of the spin-on-glass (SOG) planarizing layer employing: (1) a first thermal annealing method employing a first gaseous atmosphere comprising a non-oxidizing gas to form from the spin-on-glass (SOG) planarizing layer a cured spit-on-glass (SOG) planarizing layer; followed by (2) a second thermal annealing method employing a second gaseous atmosphere comprising an oxidizing gas to form from the cured spin-on-glass (SOG) planarizing layer an oxidized cured spin-on-glass (SOG) planarizing layer.

The method of the present invention readily commercially implemented. The present invention employs methods and materials as are otherwise generally known in the art of microelectronic fabrication. Since it is a materials selection and process control which provides at least in part the present invention, rather than the existence of methods and materials which provides the present invention, the method of the present invention is readily commercially implemented.

### BRIEF DESCRIPTION OF THE DRAWINGS

The objects, features and advantages of the present invention are understood within the context of the Description of the Preferred Embodiment, as set forth below. The Description of the Preferred Embodiment is understood within the context of the accompanying drawings, which form a material portion of this disclosure, wherein:

FIG. 1, FIG. 2, FIG. 3, FIG. 4, FIG. 5 and FIG. 6 show a series of schematic cross-sectional diagram illustrating the results of progressive stages in forming within a microelectronic fabrication in accord with a preferred embodiment of the present invention a via through a spin-on-glass (SOG) sandwich composite planarizing dielectric layer construction.

FIG. 7 shows a schematic cross-sectional diagram of a microelectronic fabrication having formed therein a spin-on-glass (SOG) sandwich composite planarizing dielectric layer construction having a via formed therethrough not in accord with the present invention.

### DESCRIPTION OF THE PREFERRED EMBODIMENT

The present invention provides a method for forming a spin-on-glass (SOG) planarizing dielectric layer within a microelectronic fabrication, where the spin-on-glass (SOG) planarizing dielectric layer is formed with enhanced properties, such as but not limited to a uniform etch profile and an enhanced adhesion for overlying layers formed upon the spin-on-glass (SOG) planarizing dielectric layer. The method of the present invention realizes the foregoing objects by employing when forming the spin-on-glass (SOG) planarizing dielectric layer: (1) a first thermal annealing of a spin-on-glass (SOG) planarizing, dielectric layer within a first thermal annealing atmosphere comprising a non-oxidizing gas to form a cured spin-on-glass (SOG) planarizing dielectric layer, followed by; (2) a second thermal annealing of the cured spin-on-glass (SOG) planarizing dielectric layer within a second thermal annealing atmosphere comprising an oxidizing gas to form from the cured spin-on-glass (SOG) planarizing dielectric layer an oxidized cured spin-on-glass (SOG) planarizing dielectric layer which exhibits the uniform etch profile and the enhanced adhesion of an overlying layer formed upon the oxidized cured spin-on-glass (SOG) planarizing dielectric layer in comparison with the cured spin-on-glass (SOG) planarizing dielectric layer.

The present invention may be employed for forming spin-on-glass (SOG) planarizing dielectric layers with enhanced properties within microelectronic fabrications including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

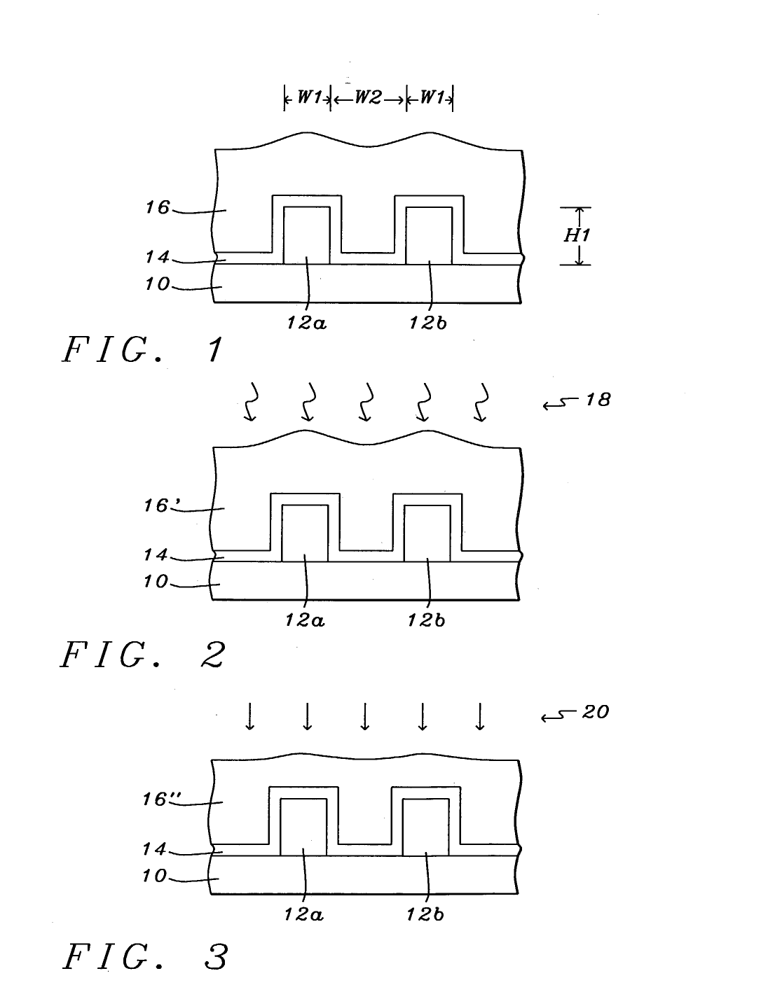

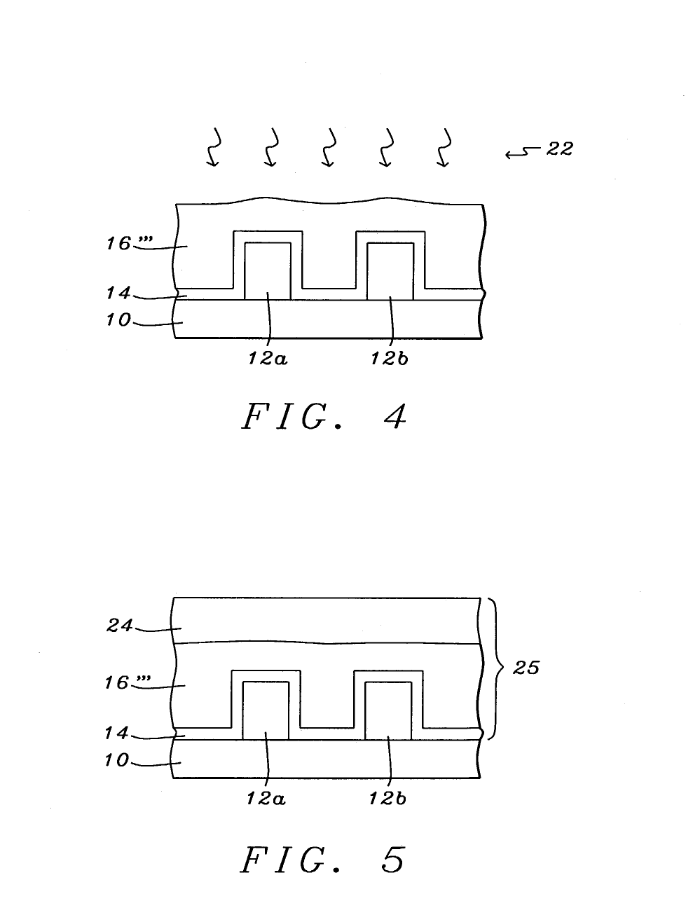

Referring now to FIG. 1 to FIG. 6, there is shown a series of schematic cross-sectional diagrams illustrating the results of forming within a microelectronic fabrication in accord with a preferred embodiment of the present invention a via through a spin-on-glass (SOG) sandwich composite planarizing dielectric layer construction. Shown in FIG. 1 is a schematic cross-sectional diagram of the microelectronic fabrication at an early stage in its fabrication in accord with the present invention.

Shown in FIG. 1 is a substrate 10 having formed thereupon a pair of patterned layers 12a and 12b.

Within the preferred embodiment of the present invention, the substrate 10 may be a substrate employed within a microelectronic fabrication selected from the group including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications. Although not specifically illustrated within the schematic cross-sectional diagram of FIG. 1, the substrate 10 may be a substrate alone employed within the microelectronic fabrication, or in the alternative, the substrate 10 may be a substrate employed within the microelectronic fabrication, where the substrate has formed thereupon and/or thereover, and thus incorporated therein, any of several additional layers as are conventional within the microelectronic fabrication within which is employed the substrate. Similarly with the substrate 10, such additional microelectronic layers may be formed of microelectronic materials including but not limited to microelectronic conductor materials, microelectronic semiconductor materials and microelectronic dielectric materials.

Similarly, although also not specifically illustrated within the schematic cross-sectional diagram of FIG. 1, the substrate 10, particularly when the substrate 10 is a semiconductor substrate employed within a semiconductor integrated circuit microelectronic fabrication, may also have formed therein and/or thereupon any of several microelectronic devices as are conventional within the microelectronic fabrication within which is employed the substrate 10. Such microelectronic devices may include, but are not limited to resistors, transistors, capacitors and diodes.

Within the preferred embodiment of the present invention with respect to the pair of patterned layers 12a and 12b, the pair of patterned layers 12a and 12b may be formed of microelectronic materials as are conventional in the art of microelectronic fabrication, such microelectronic materials being selected from the group including but not limited to microelectronic conductor materials, microelectronic semiconductor materials and microelectronic dielectric materials. As is illustrated within the schematic cross-sectional diagram of FIG. 1, each of the patterned layers 12a and 12b has a linewidth W1, typically and preferably from about 0.3 to about 3.0 microns, along with a pitch separation W2, typically and preferably from about 0.3 to about 3.0 microns, and a thickness H1, typically and preferably from about 1000 to about 12000 angstroms.

More preferably, within the preferred embodiment of the present invention, the pair of patterned layers 12a and 12b is a pair of patterned conductor layers which provides connection or interconnection within the microelectronic fabrication within which is employed the substrate 10.

Shown also within FIG. 1 formed upon the pair of patterned layers 12a and 12b and exposed portions of the substrate 10 is a blanket conformal barrier dielectric layer 14, and there is also shown formed upon the blanket conformal barrier dielectric layer 14 a blanket spin-on-glass (SOG) planarizing dielectric layer 16.

Within the preferred embodiment of the present invention the blanket conformal barrier dielectric layer 14 may under certain circumstances be optional, although under circumstances where the pair of patterned layers 12a and 12b is a pair of patterned conductor layers the blanket conformal barrier dielectric layer 14 is typically present and typically formed of a dense dielectric material, such as but not limited to a dense silicon oxide dielectric material, a dense silicon nitride dielectric material or a dense silicon oxynitride dielectric material deposited employing a plasma enhanced chemical vapor deposition (PECVD) method, although other methods and materials may be employed for forming the blanket conformal barrier dielectric layer 14. Typically and preferably, the blanket conformal barrier dielectric layer 14 is formed to a thickness of from about 500 to about 4000 angstroms from a dense dielectric material which provides a barrier against permeation of moisture and mobile conductive species.

Within the preferred embodiment of the present invention with respect to the blanket spin-on-glass (SOG) planarizing dielectric layer 16, the blanket spin-on-glass (SOG) planarizing dielectric layer 16 is formed of a silsesquioxane spin-on-glass (SOG) planarizing dielectric material as discussed in greater detail within the Description of the Related Art, and may include, but is not limited to a hydrogen silsesquioxane spin-on-glass (SOG) planarizing dielectric material, a carbon bonded hydrocarbon spin-on-glass (SOG) planarizing dielectric material or a carbon bonded fluorocarbon spin-on-glass (SOG) planarizing dielectric material, although a methyl silsesquioxane spin-on-glass (SOG) planarizing dielectric material is typically most preferred. Preferably, the silsesquioxane spin-on-glass (SOG) planarizing dielectric material from which is formed the spin-on-glass (SOG) planarizing dielectric layer 16 is provided as a solution of the pertinent silsesquioxane spin-on-glass (SOG) planarizing dielectric material in an appropriate solvent, often but not exclusively an alcohol, along with appropriate catalysts, diluents and additives. Typically and preferably, the blanket spin-on-,lass (SOG) plagiarizing dielectric layer 16 is formed to a thickness of from about 1000 to about 10000 angstroms.

Referring now to FIG. 2, there is shown a schematic cross-sectional diagram illustrating the results of further processing of the microelectronic fabrication whose schematic cross-sectional diagram is illustrated in FIG, 1.

Shown in FIG. 2 is a schematic cross-sectional diagram of a microelectronic fabrication otherwise equivalent to the microelectronic fabrication whose schematic cross-sectional diagram is illustrated in FIG. 1, but wherein the blanket spin-on-glass (SOG) planarizing dielectric layer 16 has been thermally annealed within a first thermal annealing atmosphere 18 to form from the blanket spin-on-glass (SOG) planarizing dielectric layer 16 a blanket cured spin-on-glass (SOG) planarizing dielectric layer 16′.

Within the preferred embodiment of the present invention, the first thermal annealing atmosphere 18 is employed within a first thermal annealing method which employs a non-oxidizing annealing gas. Although within the present invention and the preferred embodiment of the present invention the non-oxidizing annealing gas employed within the first thermal annealing atmosphere is preferably nitrogen, other non-oxidizing annealing gases, such as but not limited to argon, helium and mixtures thereof, may also be employed, although oxidizing annealing gases are excluded from the first thermal annealing atmosphere 18. Preferably, the first thermal annealing method also employs, when processing the blanket spin-on-glass (SOG) planarizing dielectric layer 16 formed upon an eight inch diameter substrate: (1) a first thermal annealing chamber pressure of from about 1 to about 50 torr; (2) a first thermal annealing chamber temperature of from about 300 to about 500 degrees centigrade; and (3) a nitrogen flow rate of from about 1000 to about 10000 standard cubic centimeters per minute (sccm).

Although FIG. 1 and FIG. 2 illustrate a single blanket spin-on-glass (SOG) planarizing dielectric layer 16 thermally annealed within a single first thermal annealing atmosphere 18, it is understood by a person skilled in the art that it is common within the art of microelectronic fabrication that there may be employed multiple sub-layers of the blanket spin-on-glass (SOG) planarizing dielectric layer 16 and multiple sequential exposures to a first thermal annealing atmosphere, such as the first thermal annealing atmosphere 18, in order to provide the blanket cured spin-on-glass (SOG) planarizing dielectric layer 16′ which is an aggregate of blanket cured spin-on-glass (SOG) planarizing dielectric sub-layers. Within the preferred embodiment of the present invention, it is typical and preferred that the blanket cured spin-on-glass (SOG) planarizing dielectric layer 16′ be formed of an aggregate of three such blanket cured spin-on-glass (SOG) planarizing dielectric sub-layers. When employing the blanket spin-on-glass (SOG) planarizing dielectric layer 16 as either a mono-layer or as an aggregate of sub-layers, there is typically observed nominal shrinkage of the blanket cured spin-on-g,lass (SOG) planarizing dielectric layer 16′ with respect to the blanket spin-on-(glass planarizing dielectric layer 16 of from about 1 to about 20 percent.

Referring now to FIG. 3, there is shown a schematic cross-sectional diagram illustrating the results of further processing of the microelectronic fabrication whose schematic cross-sectional diagram is illustrated in FIG. 2.

Shown in FIG. 3 is a schematic cross-sectional diagram of a microelectronic fabrication otherwise equivalent to the microelectronic fabrication whose schematic cross-sectional diagram is illustrated in FIG. 2, but wherein the blanket cured spin-on-glass (SOG) planarizing dielectric layer 16′ has been etched back, while employing an etch back plasma 20, to form a blanket etched back cured spin-on-glass (SOG) planarizing dielectric layer 16″.

Although the etchback planarizing of the blanket cured spin-on-glass (SOG) planarizing dielectric layer 16′ to form the blanket etched back cured spin-on-glass (SOG) planarizing dielectric layer 16″ is optional within the present invention, it is typically undertaken insofar as it provides planarizing of the blanket etched back cured spin-on-glass (SOG) planarizing dielectric layer 16″ with respect to the blanket cured spin-on-glass (SOG) planarizing dielectric layer 16′. Within the present invention, the etch back plasma 20 typically and preferably employs an etchant gas composition which upon plasma activation forms an active fluorine containing etchant species, along with appropriate diluent and/or stabilizing gases. Such active fluorine containing etchant species may be derived from etchant gases including but not limited to perfluorocarbons, hydrofluorocarbons, sulfur hexafluoride and nitrogen trifluoride.

Within the preferred embodiment of the present invention, the etch back plasma 20 preferably employs an etchant gas composition comprising carbon tetrafluoride, trifluoromethane and argon. Preferably, when etching back the blanket cured spin-on-glass (SOG) planarizing dielectric layer 16′ formed upon an eight inch diameter substrate 10, the etch back plasma 20 also employs: (1) a reactor chamber pressure of from about 0.2 to about 1 torr; (2) a source radio frequency power of from about 200 to about 600 watts at a source radio frequency of 13.56 MHZ, without a bias power; (3) a substrate 10 temperature of from about zero to about −20 degrees centigrade; (4) a carbon tetrafluoride flow rate of from about 5 to about 40 standard cubic centimeters per minute (sccm), (5) a trifluoromethane flow rate of from about 5 to about 20 standard cubic centimeters per minute (sccm); and (6) an argon flow rate of from about 100 to about 600 standard cubic centimeters per minute (sccm). Typically and preferably, the etch back plasma 20 is employed to remove from about 1000 to about 5000 angstroms of the blanket cured spin-on-glass (SOG) planarizing dielectric layer 16′ when forming the blanket etched back cured spin-on-glass (SOG) planarizing dielectric layer 16″.

Referring now to FIG. 4, there is shown a schematic cross-sectional diagram illustrating the results of further processing of the microelectronic fabrication whose schematic cross-sectional diagram is illustrated in FIG. 3.

Shown in FIG. 4 is a schematic cross-sectional diagram of a microelectronic fabrication otherwise equivalent to the microelectronic fabrication whose schematic cross-sectional diagram is illustrated in FIG. 3, but wherein the blanket etched back cured spin-on-glass (SOG) planarizing dielectric layer 16″ has been oxidized within a second thermal annealing atmosphere 22 to form a blanket oxidized etched back cured spin-on-glass (SOG) planarizing dielectric layer 16′″.

Within the present invention and the preferred embodiment of the present invention, the second thermal annealing atmosphere 22 is employed within a second thermal annealing method which employs an oxidizing gas at a sufficient temperature and pressure to form from the blanket etched back cured spin-on-glass (SOG) planarizing dielectric layer 16″ the blanket oxidized etched back cured spin-on-glass (SOG) planarizing dielectric layer 16′″ which possesses enhanced properties, such as but not limited to uniform etch profile properties and enhanced adhesion properties with respect to overlying layers formed upon the blanket oxidized etched back cured spin-on-glass (SOG) planarizing dielectric layer 16′″. Within the present invention, the second thermal annealing atmosphere 22 may employ an oxidizing gas selected from the group including but not limited to oxygen, ozone, nitrous oxide and nitric oxide, as well as mixtures thereof, with or without non-oxidizing diluents, although the oxidizing gas is preferably oxygen alone. When oxidizing the blanket etched back cured spin-on-glass (SOG) planarizing layer 16″ upon an eight inch diameter substrate 110 to form the blanket oxidized etched back cured spin-on-glass (SOG) planarizing layer 16′″, the second thermal annealing method which employs the oxidizing gas typically also preferably employs: (1) a second thermal annealing chamber pressure of from about 1 to about 50 torr; (2) a second thermal annealing chamber temperature of from about 350 to about 500 degrees centigrade; and (3) an oxygen flow rate of from about 1000 to about 9000 standard cubic centimeters per minute (sccm).

Significant to the present invention is the limitation that the second thermal annealing atmosphere which employs the oxidizing gas is preferably provided without the assistance of any plasma activation. Rather, the second thermal annealing method is preferably solely a thermal annealing method which may employ a conventional thermal annealing furnace apparatus (which provides a temperature gradient of from about 0.5 to about 10 degrees centigrade per minute) or a rapid thermal processing (RTP) thermal processing apparatus (which provides a temperature gradient of from about 50 to about 200 degrees centigrade per second).

Referring now to FIG. 5, there is shown a schematic cross-sectional diagram illustrating the results of further processing of the microelectronic fabrication whose schematic cross-sectional diagram is illustrated in FIG. 4.

Shown in FIG. 5 is a schematic cross-sectional diagram of a microelectronic fabrication otherwise equivalent to the microelectronic fabrication whose schematic cross-sectional diagram is illustrated in FIG. 4, but wherein there is formed upon the blanket oxidized etched back cured spin-on-glass (SOG) planarizing dielectric layer 16′″ a blanket cap dielectric layer 24. Within the microelectronic fabrication whose schematic cross-sectional diagram is illustrated in FIG. 5, the blanket conformal barrier dielectric layer 14, the blanket oxidized etched back cured spin-on-glass (SOG) planarizing dielectric layer 16′″ and the blanket cap dielectric layer 24 in the aggregate form a blanket composite planarizing spin-on-glass (SOG) dielectric layer construction 25.

Within the preferred embodiment of the present invention, the blanket dielectric cap layer 24 may be formed employing methods and materials as are conventional in the art of microelectronic fabrication, which will typically and preferably employ methods and materials analogous or equivalent to the methods and materials employed for forming the blanket conformal barrier dielectric layer 14. Within the preferred embodiment of the present invention, adhesion of the blanket cap dielectric layer 24 to the blanket oxidized etched back cured spin-on-glass (SOG) planarizing dielectric layer 16′″ is enhanced with respect to adhesion of the blanket dielectric cap layer 24 to either the blanket cured spin-on-glass, (SOG) planarizing dielectric layer 16′ or the blanket etched back cured spin-on-glass (SOG) planarizing dielectric layer 16″ insofar as the blanket oxidized etched back cured spin-on-glass (SOG) planarizing dielectric layer 16′″ has been oxidized through treatment with the oxidizing gas within the second thermal annealing atmosphere 22.

While not wishing to be bound to any particular theory of operation of the present invention, it is believed that by oxidizing the blanket etched back cured spin-on-glass (SOG) planarizing dielectric layer 16″ there is effected a surface modification when forming the blanket oxidized etched back cured spin-on-glass (SOG) planarizing dielectric layer 16′″ such that any of several overlying layers formed thereupon, such as but not limited to the blanket cap dielectric layer 24, may be formed with greater adhesion.

Referring now to FIG. 6, there is shown a schematic cross-sectional diagram illustrating the results of further processing of the microelectronic fabrication whose schematic cross-sectional diagram is illustrated in FIG. 5.

Shown in FIG. 6 is a schematic cross-sectional diagram of a microelectronic fabrication otherwise equivalent to the microelectronic fabrication whose schematic cross-sectional diagram is illustrated in FIG. 5, but wherein, in a first instance, there is formed upon the blanket dielectric cap layer 24 a series of patterned photoresist layers 26a, 26b and 26c. The series of patterned photoresist layers 26a, 26b and 26c may be formed employing methods as are conventional in the art of microelectronic fabrication, where such methods may employ photoresist materials selected from the general groups of photoresist materials including but not limited to positive photoresist materials and negative photoresist materials. Typically and preferably, the series of patterned photoresist layers 26a, 26b and 26c is formed of a positive photoresist material, in order to provide optimal dimensional stability when forming the series of patterned photoresist layers 26a, 26b and 26c. Typically and preferably, the series of patterned photoresist layers 26a, 26b and 26c is formed to a thickness of from about 8000 to about 20000 angstroms to define a pair of apertures aligned centered above each of the patterned layers 12a and 12b.

There is also shown in FIG. 6 the results of sequentially etching the blanket cap dielectric layer 24, the blanket oxidized etched back cured spin-on-glass (SOG) planarizing dielectric layer 16′″ and the blanket conformal barrier dielectric layer 14 to form a corresponding series of patterned cap dielectric layers 24a, 24b and 24c formed and aligned upon a corresponding series of patterned oxidized etched back cured spin-on-glass (SOG) planarizing dielectric layers 16a′″, 16b′″ and 16c′″ in turn formed upon a series of patterned conformal barrier dielectric layers 14a, 14b and 14c. Within the preferred embodiment of the present invention, the patterned cap dielectric layer 24 is patterned to form the series of patterned cap dielectric layers 24a, 24b and 24c, the blanket oxidized etched back cured spin-on-glass (SOG) planarizing dielectric layer 16′″ is patterned to form the series of patterned oxidized etched back cured spin-on-glass (SOG) planarizing dielectric layers 16a′″, 16b′″ and 16c′″ and the blanket conformal barrier dielectric layer 14 is patterned to form the series of patterned conformal barrier dielectric layers 14a, 14b and 14c while employing a wet chemical etchant, typically and preferably a hydrofluoric acid containing wet chemical etchant (such as but not limited to dilute aqueous hydrofluoric acid etchant or a buffered oxide etchant (BOE)), although other etchants, including but not limited to dry plasma etchants, which employ fluorine (such as but not limited to fluorocarbon) containing etchant gas compositions, may also be employed.

As is illustrated within the schematic cross-sectional diagram of FIG. 6, the sidewalls of a pair of vias 27a and 27b formed in part by the series of patterned oxidized etched back cured spin-on-glass (SOG) planarizing dielectric layers 16a′″, 16b′″ and 16c′″ is formed with uniform etch profile (i.e. uniform sidewall profile) thus indicating a uniform etch rate.

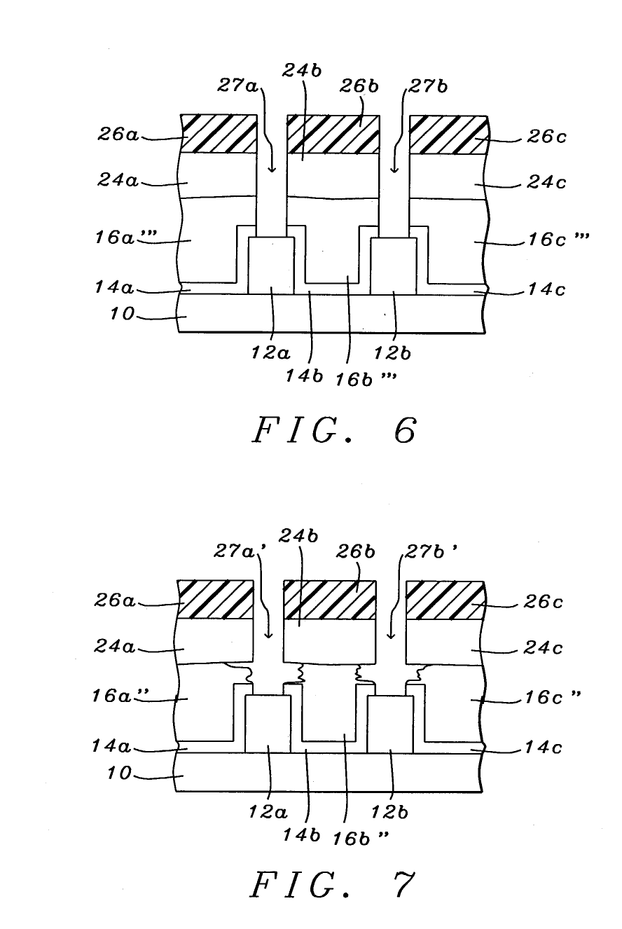

For comparison purposes, there is illustrated within FIG. 7 a schematic cross-sectional diagram of a microelectronic fabrication analogous to the microelectronic fabrication whose schematic cross-sectional diagram is illustrated within FIG. 6, and which results from etching a microelectronic fabrication otherwise equivalent to the microelectronic fabrication whose schematic cross-sectional diagram is illustrated in FIG. 5, but wherein there is employed the blanket etched back cured spin-on-glass (SOG) planarizing dielectric layer 16″ in place of the blanket oxidized etched back cured spin-on-glass (SOG) planarizing dielectric layer 16′″. As is illustrated within the schematic cross-sectional diagram of FIG. 7, a pair of vias 27a′ and 27b′ defined in part by a series of patterned etched back cured spin-on-glass (SOG) planarizing layers 16a″, 16b″ and 16c″ is formed with less uniform etch profile in comparison with the pair of vias 27a and 27b as illustrated within the schematic cross-sectional diagram of FIG. 6.

Although not wishing to be bound to any particular theory as to why there is formed a more uniform etch profile within the vias 27a and 27b within the microelectronic fabrication whose schematic cross-sectional diagram is illustrated in FIG. 6 in comparison with the corresponding etch profile within the vias 27a′ and 27b′ within the microelectronic fabrication whose schematic cross-sectional diagram is illustrated in FIG. 7, it is believed that by employing the second thermal annealing atmosphere employing the oxidizing gas when forming from the blanket etched back cured spin-on-glass (SOG) planarizing dielectric layer 16″ the blanket oxidized etched back cured spin-on-glass (SOG) planarizing dielectric layer 16′″, there is more fully oxidized any imperfections and occlusions which are formed within the blanket etched back cured spin-on-glass (SOG) planarizing layer 16″ such that there is uniform etching within an isotropic etchant, such as a wet chemical etchant employed for forming the pair of vias 27a and 27b.

The microelectronic fabrication whose schematic cross-sectional diagram is illustrated in FIG. 6 may be further fabricated employing methods and materials as are conventional in the art for forming the microelectronic fabrication whose schematic cross-sectional diagram is illustrated in FIG. 6. Typically and preferably, incident to such further fabrication, the patterned photoresist layers 26a, 26b and 26c are stripped from the microelectronic fabrication whose schematic cross-sectional diagram is illustrated in FIG. 6, prior to further processing of the microelectronic fabrication whose schematic cross-sectional diagram is illustrated in FIG. 6.

As is understood by a person skilled in the art, the preferred embodiment of the present invention is illustrative of the present invention rather than limiting of the present invention. Revisions and modifications may be made to methods, materials, structures and dimensions through which is fabricated a microelectronic fabrication in accord with the preferred embodiment of the present invention, while still providing a microelectronic fabrication in accord with the present invention, as defined by the appended claims.

What is claimed is:

1. A method for forming a spin-on-glass (SOG) layer comprising:
providing a substrate;
forming over the substrate a spin-on-glass (SOG) planarizing layer while employing a silsesquioxane spin-on-glass (SOG) planarizing material;
annealing thermally, while employing a first thermal annealing method, the spin-on-glass (SOG) planarizing layer within a first gaseous atmosphere comprising a non-oxidizing gas to form from the spin-on-glass (SOG) planarizing layer a cured spin-on-glass (SOG) planarizing layer; and
annealing thermally, while employing a second thermal annealing method, the cured spin-on-glass (SOG) planarizing layer within a second gaseous atmosphere comprising an oxidizing gas to form from the cured spin-on-glass (SOG) planarizing layer an oxidized cured spin-on-glass (SOG) planarizing layer.

2. The method of claim 1 wherein when annealing thermally the cured spin-on-glass (SOG) planarizing layer while employing the second thermal annealing method within the second gaseous atmosphere comprising the oxidizing gas there is not employed a plasma activation of the oxidizing gas.

3. The method of claim 1 wherein the substrate is employed within a microelectronic fabrication selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

4. The method of claim 1 wherein the silsesquioxane spin-on-glass (SOG) planarizing material is selected from the group consisting of hydrogen silsesquioxane spin-on-glass (SOG) planarizing materials, carbon bonded hydrocarbon silsesquioxane spin-on-glass (SOG) planarizing materials and carbon bonded fluorocarbon silsesquioxane spin-on-glass (SOG) planarizing materials.

5. The method of claim 1 wherein the oxidizing gas is selected from the group consisting of oxygen, ozone, nitrous oxide and nitric oxide.

6. The method of claim 1 further comprising forming upon the oxidized cured spin-on-glass (SOG) planarizing layer a cap dielectric layer, wherein adhesion of the cap dielectric layer is enhanced upon the oxidized cured spin-on-glass (SOG) planarizing layer in comparison with the cured spin-on-glass (SOG) planarizing layer.

7. The method of claim 1 further comprising:
forming over the oxidized cured spin-on-glass (SOG) planarizing layer a patterned photoresist layer; and
etching a portion of the oxidized cured spin-on-glass (SOG) planarizing layer while employing a wet chemical etch method to form an etched oxidized cured spin-on-glass (SOG) planarizing layer, wherein by thermally annealing the cured spin-on-glass (SOG) planarizing layer while employing the second thermal annealing method employing the second gaseous atmosphere comprising the oxidant gas there is provided a more uniform etch profile of the etched oxidized cured spin-on-glass (SOG) planarizing layer.

8. A method for forming a spin-on-glass (SOG) layer comprising:
providing a substrate;
forming over the substrate a spin-on-glass (SOG) planarizing layer while employing a silsesquioxane spin-on-glass (SOG) planarizing material;
annealing thermally, while employing a first thermal annealing method, the spin-on-glass (SOG) planarizing layer within a first gaseous atmosphere comprising a non-oxidizing gas to form from the spin-on-glass (SOG) planarizing layer a cured spin-on-glass (SOG) planarizing layer;
etching back the cured spin-on-glass (SOG) planarizing layer to form an etched back cured spin-on-glass (SOG) planarizing layer; and
annealing thermally, while employing a second thermal annealing method, the etched back cured spin-on-glass (SOG) planarizing layer within a second gaseous atmosphere comprising an oxidizing gas to form from the etched back cured spin-on-glass (SOG) planarizing layer an oxidized etched back cured spin-on-glass (SOG) planarizing layer.

9. The method of claim 8 wherein when annealing thermally the etched back cured spin-on-glass (SOG) planarizing layer while employing the second thermal annealing method employing the second gaseous atmosphere comprising the oxidizing gas there is not employed a plasma activation of the oxidizing gas.

10. The method of claim 8 wherein the substrate is employed within a microelectronic fabrication selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

11. The method of claim 8 wherein the silsesquioxane spin-on-glass (SOG) planarizing material is selected from the group consisting of hydrogen silsesquioxane spin-on-glass (SOG) planarizing materials, carbon bonded hydrocarbon silsesquioxane spin-on-glass (SOG) planarizing materials and carbon bonded fluorocarbon silsesquioxane spin-on-glass (SOG) planarizing materials.

12. The method of claim 8 wherein the oxidizing gas is selected firm the group consisting of oxygen, ozone, nitrous oxide and nitric oxide.

13. The method of claim 8 further comprising forming upon the oxidized etched back cured spin-on-glass (SOG) planarizing layer a cap dielectric layer, wherein adhesion of the cap dielectric layer is enhanced upon the oxidized etched back cured spin-on-glass (SOG) planarizing layer in comparison with the etched back cured spin-on-glass (SOG) planarizing layer.

14. The method of claim 8 further comprising:
forming over the oxidized etched back cured spill-on-glass (SOG) planarizing layer a patterned photoresist layer; and
etching a portion of the oxidized etched back cured spin-on-glass (SOG) planarizing layer employing a wet chemical etch method to form an etched oxidized etched back cured spin-on-glass (SOG) planarizing layer, wherein by thermally annealing the etched back cured spin-on-glass (SOG) planarizing layer while employing the second thermal annealing method while employing the gaseous atmosphere comprising the oxidant gas there is provided a more uniform etch profile of the etched oxidized etched back cured spin-on-glass (SOG) planarizing layer.
